(19) United States
(12) Patent Application Publication
(10) Pub. No.: US 2011/0173807 A1
(43) Pub. Date: Jul. 21, 2011

(54) DISPERSION FOR DISPOSING FINE PARTICLE AT PREDETERMINED POINT ON SUBSTRATE BY INK-JET PRINTING

(75) Inventors: Masahiro Kuzawa, Nagoya (JP); Katsumi Hara, Nagoya (JP); Michio Doi, Nagoya (JP); Hideaki Kato, Nagoya (JP)

(73) Assignee: NATOCO CO., LTD., MIYOSHI-SHI, AICHI (JP)

(21) Appl. No.: 13/062,437

(22) PCT Filed: Sep. 25, 2009
(86) PCT No.: PCT/JP2009/067193

§ 371 Date: Mar. 22, 2011

(30) Foreign Application Priority Data
Sep. 26, 2008 (JP) 2008-248104

(51) Int. Cl. H05K 3/00; C08K 5/053

(52) U.S. Cl. 29/829; 524/766

(57) ABSTRACT

It is provided a dispersion for positioning and adhering fine particles at predetermined positions on a substrate upon heating by ink jet printing. The dispersion comprises spacers, a solvent and an adhesive additive. The adhesive additive has an average molecular weight (Mw) of 3600 or lower and a property of forming a polymer upon heating.

### 1. FIELD OF THE INVENTION

The present invention relates to a dispersion for positioning fine particles at predetermined positions on a substrate by ink jet printing.

### BACKGROUND ARTS

According to a prior process of manufacturing a liquid crystal displaying device, spacers are distributed randomly on a substrate with pixel electrodes is formed thereon. The spacers are also positioned on its displaying section to cause leakage of light around the spacers, which is problematic. Then, it has been studied a method of positioning spacers at predetermined positions only on the non-displaying sections of a substrate by ink jet printing. When the spacers are positioned on the non-displaying sections, however, the spacers may be peeled off from the non-displaying sections and moved to the displaying sections in the case that an outer strong force is applied on a panel and the adhesive force of the spacers to the substrate is low. This problem becomes considerable as the size of the panel is larger.

For preventing such problems, it is used a method of blending a water soluble adhesive or adhesive particles having a size of about one-tenth of that of the spacers. According to Japanese Patent No. 3,997,038B and Japanese patent Publication No. H09-105,946A, it is disclosed a method of blending an adhesive resin into a spacer dispersion to improve the adhesiveness of the spacers onto a substrate.

Japanese Patent Publication No. 2000-347,191A discloses a method of blending adhesive particles having a softening point of 50 to 160° C. and Japanese Patent Publication No. 2007-33,797A discloses a method of blending adhesive particles having a softening point of 40 to 120° C. in spacer dispersions to improve the adhesiveness of the spacers onto a substrate.

Japanese Patent Publication No. 2008-145,513A discloses a method of discharging spacer particles stably through a nozzle for the positioning at predetermined positions, by defining the viscosity of a dispersion of spacer particles.

Further, Japanese Patent Publication No. 2008-224,849A discloses a method of adding an adhesive containing a bridged polymer having a weight average molecular weight of 1000 to 300,000 into a liquid crystal spacer dispersion. It is described that, if the molecular weight is lower than 1000, an amount of sol content in a solidified product of the liquid crystal spacer dispersion is increased to result in contamination of liquid crystal in the production of a liquid crystal displaying device.

### SUMMARY OF THE INVENTION

When the adhesive resin as described in Japanese Patent No. 3,997,038B or Japanese patent Publication No. H09-105,946A is used, however, it is possible that the adhesive resin would not be fully joined together before the liquid drops are dried. Recently, the definition of a panel is improved and the areas of the non-displaying sections are made smaller, and in the recent cases, a part of the liquid drops before the drying may contact the displaying sections. If the resin would not be fully joined together in such case, it is concerned that the adhesive resin may remain on the pigment sections to result in contamination of alignment films of the displaying sections to cause light leak and deterioration of display quality.

When the adhesive particles dispersed in the dispersion is used as described in Japanese Patent Publication Nos. 2000-347191A and No. 2007-33797A, the adhesive particles might not be fully joined together onto the spacers. It is thus concerned that the alignment films are contaminated in the pigment sections to result in deterioration of display quality. Further, the particles of sub-micron sizes (0.3 μm in examples of Japanese Patent Publication No. 2000-347,191A; 0.25 μm in examples of Japanese Patent Publication No. 2007-33, 739A tend to be aggregated and it is thus concerned that the dispersion property is deteriorated.

For solving the problems of the alignment film contamination, the applicant proposed a method disclosed in PCT/JP2008/056635 (WO 2008/123569A1).

Further, the applicant filed the following international applications in the art of spacer dispersion for ink jet printing device.

PCT/JP2008/061069 (WO 2009/44571A1)

PCT/JP2008/061068 (WO 2009/84256A1)

An object of the present invention is to provide a dispersion for obtaining a strong adhesive force between spacers and a substrate without contaminating alignment films.

The present invention provides a dispersion for positioning and adhering fine particles upon heating at predetermined positions on a substrate by ink jet printing, said dispersion comprising spacers, a solvent and an adhesive additive, wherein said adhesive additive has an average molecular weight (Mw) of 3600 or lower and a property of polymerizing by heating.

The present invention further provides a method of producing a liquid crystal display device, the method comprising the steps of:

positioning the dispersion on non-displaying sections of at least one of a first substrate and a second substrate by means of an ink jet printing system;

drying the dispersion; and

opposing and then fixing said first and second substrates through said spacers and a liquid crystal.

According to the spacer dispersion of the present invention, it is possible to obtain a strong adhesive force of the spacers and the substrate without contaminating alignment films.

### BRIEF DESCRIPTION OF THE DRAWINGS

FIG. 1 is a photograph showing surface state of an alignment film after a spacer ink is printed, according to an example 1.

FIG. 2 is a photograph showing surface state of an alignment film after a spacer ink is printed, according to a comparative example 1.

### PREFERRED EMBODIMENTS OF THE INVENTION

Ingredients of the inventive dispersion of fine particles will be described below.

### (Adhesive Additive)

The adhesive additive added in the dispersion according to the present invention has an average molecular weight (Mw) of 3600 or less and forms a polymer upon heating condition for adhering the fine particles.

That is, the molecular weight of the additive is relatively low at the stage of the dispersion and exhibits adhesive force of the spacers after the heating by the polymerization. Such additive is used for adhesiveness of the spacers to successfully obtain a desired adhesive force while preventing the contamination of the alignment films.

The adhesive additive has an average molecular weight (Mw) of 3600 or lower. The average molecular weight is measured by means of a high-performance GPC system using tetrahydrofuran as a dilution solvent.

The molecular weight (Mw) of the adhesive additive is 3600 or lower on the viewpoint of the present invention and may preferably be 2000 or lower and more preferably be lower than 1000. When Mw is lower than 1000, the adhesive additive tends to gather near the roots of the particles so that it is expected a further improvement of the adhesive force. On the viewpoint, Mw may more preferably be 950 or lower, further preferably be 765 or lower and still further preferably be 378 or lower. On the viewpoint of preventing the vaporization of the adhesive additive during the heating for the adhesion, the average molecular weight (Mw) of the adhesive additive may preferably be 100 or larger.

It is necessary that the adhesive additive forms a polymer upon heating. Here, the dispersion is heated so that the spacers adhere the substrate, and the heating conditions are different with each other depending on products. However, when the adhesive additive forms a polymer upon heating at 200° C., it is sufficient for the object of the present invention.

Further, the polymerization means that the adhesive additive molecules react with each other to increase the average molecular weight Mw. The average molecular weight is increased to 10 times or more of that before the polymerization, for example. Here, on the viewpoint of adhesion force, the average molecular weight Mw of the adhesive additive after the heating may preferably be 3600 or higher and more preferably be 4600 or higher. In some cases, the polymerization of the additive may be so progressed that the product may be insoluble in tetrahydrofuran. In this case, it is impossible to measure the average molecular weight Mw of the product by means of the above described method. Of course, since the polymerization is further progressed in such cases, it is embraced within the present invention.

Specific examples of the adhesive additive include a titanium coupling agent, an alkylated melamine resin having a plurality of alkylol groups, an alkylated amino resin having a plurality of alkylol groups and the like.

The adhesive additive may more preferably be the followings.

### (Phenol-Methylol Compounds)

A phenol-methylol compound used in the present invention is not particularly limited, as far as the compound includes two or more methylol groups and phenolic structure in the molecule.

If the number of methylol groups is too large, the reactivity of the molecule would become too high and it would be concerned the deterioration of its stability during the storage. Then, on the viewpoint of the storage stability, the number of methylol groups may preferably be 3 or less with respect to one phenyl group in a single molecule.

The phenolic structure includes phenols, cresols, xylenols, alkylphenols and polyhydric phenols, for example. The cresols include o-cresol, m-cresol, and p-cresol. The xylenols include 2,3-xylenol, 2,4-xylenol, 2,5-xylenol, 2,6-xylenol, 3,4-xylenol and 3,5-xylenol. The alkylphenols include 2-ethylphenol, 4-ethylphenol, 2-i-propylphenol, 2-t-butylphenol, 4-t-butylphenol, 2-cyclohexylphenol, 4-cyclohexylphenol, thymol, 3-methyl-t-butylphenol, 3-methyl-6-cyclohexylphneol, 2,3,5-trimethylphenol, and 2,3,6-trimethylphenol. The polyhydric phenols include resorcin, cathecol, hydroquinone, pyrogallol and 2-methylresorcin.

Specifically, they are included 2,6-dihydroxymethyl-4-methyl phenol, 2,4-dihydroxymethyl-6-methyl phenol, 2,6-dihydroxymethyl-3,4-dimethyl phenol, 4,6-dihydroxymethyl-2,3-dimethyl phenol, 4-t-butyl-2,6-dihydroxymethyl phenol, 4-cyclohexyl-2,6-dihydroxymethyl phenol, 2-cyclohexyl-4,6-dihydroxymethyl phenol, 2,6-dihydroxymethyl-4-ethyl phenol, 4,6-dihydroxymethyl-2-ethyl phenol, 4,6-dihydroxymethyl-2-isopropyl phenol, 6-cyclohexyl-2,4-hydroxymethyl-3-methyl phenol, 2,4,6-trihydroxymethyl phenol, bis(2 hydroxy-3-hydroxymethyl-5-methyl phenol) methane, bis(4-hydroxy-3-hydroxymethyl-5-methyl phenol) methane, bis (4-hydroxy-3-hydroxy methyl-2,5-dimethyl phenol) methane, bis (4-hydroxy-5-hydroxymethyl-2,3-dimethyl phenol) methane, bis (2-hydroxy-3-hydroxymethyl-4,5-dimethyl phenol) methane, 2,2-his (4-hydroxy-3,5-dihydroxymethyl phenol) methane, 2,2-bis (4-hydroxy-3,5-dihydroxymethyl phenol) propane and the like.

### (Silane Compound)

Silane compound is not particularly limited, as far as it includes a plurality of hydrolysable alkoxy groups in a single molecule and has a molecular weight of 3600 or less.

Representative structures are listed below.

X˜˜˜˜Si(OR₁)₃ or X˜˜˜˜Si(OR₁)₂R₂

X represents alkyl, phenyl, vinyl, epoxy, amino, methacryl, mercapt, alkoxy silyl group or the like,

OR₁ (alkoxy group) is methoxy, ethoxy, n-propoxy, i-propoxy, n-butoxy, t-butoxy group or the like.

R₂ represents alkyl group.

When the number of the hydrolysable alkoxy groups is too large and the ink contains water, the ink tends to be influenced by the hydrolysation during the storage. Further, when the number of the hydrolysable alkoxy groups is too large, it would be concerned that the bridging density becomes too large and the adhesive after the adhesion upon heating becomes too hard to injure alignment films. Then, on the viewpoints of stability on storage and preventing injury of alignment films, the number of the hydrolysable alkoky groups contained in a single molecule of the silane compound may preferably be 9 or less and more preferably be 6 or less.

Specifically, they are listed phenyltriethoxysilane, hexyltrimethoxysilane, decyltrimethoxysilane, vilyltrimethoxysilane, vinyltriethoxysilane, 2-(3,4-epoxycyclohexyl)ethyltrimethoxysilane, 2-(3,4-epoxycyclohexyl)ethyltriethoxysilane, 3-glycidoxypropylmethyldimethoxysilane, 3-glycidoxypropylmethyldiethoxysilane, 3-glycidoxypropyltrimethoxysilane, 3-glycidoxypropylmethyldiethoxysilane, 3-glycidoxypropyltriethoxysilane, p-styryltrimethoxysilane, p-styryltriethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane N-2-(aminoethyl)-3-aminopropylmethyldimethoxysilane, N-2-(aminoethyl)-3-aminopropyltrimethoxysilane, N-2-(aminoethyl)-3-aminopropylmethyldiethoxysilane N-2-(aminoethyl)-3-aminopropyltriethoxysilane, 3-aminopropyltrimethoxysilane, 3-aminopropyltriethoxysilane, 3-triethoxysilyl-N-(1,3-dimethylbutyrydene)propylamine N-phenyl-3-aminopropyltrimethoxysilane, γ-isocyanatepropyltriethoxysilane, 3-ureidopropyltriethoxysilane, 3-chloropropyltrimethoxysilane, 3-mercaptopropylmethyldimethoxysilane, 3-mercaptopropyltrimethoxysilane, 3-mercaptopropylmethyldiethoxysilane, 3-mercaptopropyltriethoxysilane, bis(triethoxysilylpropyl)tetrasulfide, bis(trimethoxysilyl)ethane, 3-isocyanatepropyltriethoxysilane tris-(3-trimethoxysilylpropyl)isocyanurate or the like.

### (Dispersing Medium)

The organic dispersing medium includes the followings.

It is listed monoalcohols such as methanol, ethanol, n-propanol, 2-propanol, 1-butanol, 2-butanol, 1-methoxy-2-propanaol, furfuryl alcohol, tetrahydrofurfuryl alcohol, cyclopentanol, cyclohexanol or the like.

It is further listed ethylene glycol and multimers of ethylene glycol such as diethylene glycol, triethylene glycol, tetraethylene glycol or the like; low molecular weight monoalkyl ethers such as monomethyl ethers, monoethyl ethers, monoisopropyl ethers, monopropyl ethers, monobutyl ethers of the above or the like; low molecular weight dialkyl ethers such as dimethyl ethers, diethyl ethers, diisopropyl ethers, dipropyl ethers or the like; and alkyl esters such as monoacetate, diacetate or the like.

It is further listed propylene glycol and multimers of propylene glycol such as dipropylene glycol, tripropylene glycol, tetrapropylene glycol or the like; low molecular weight monoalkyl ethers such as monomethyl ethers, monoethyl ethers, monoisopropyl ethers, monopropyl ethers, monobutyl ethers of the above or the like; low molecular weight dialkyl ethers such as dimethyl ethers, diethyl ethers, diisopropyl ethers, dipropyl ethers or the like; and alkyl esters such as monoacetate, diacetate or the like.

It is further listed diols such as 1,3-propanediol, 1,2-butanediol, 1,3-butanediol, 1,4-butanediol, 3-methyl-1,5-pentanediol, 3-hexene-2,5-diol, 1,5-pentanediol, 2,4-pentanediol, 2-methyl-2,4-pentanediol, 2,5-hexanediol, 1,6-hexanediol, neopentylglycol or the like; ether derivatives of the diols; acetate deriveatives of the diols; polyhydric alcohols such as glycerin, 1,2,4-butanetriol, 1,2,6-hexanetriol, 1,2,5-pentanetriol, trimethylolpropane, trimethylol ethane, pentaerythritol or the like, and their ether derivatives and acetate deriveatives.

It is further listed dimethylsulfoxide, thiodiglycol, N-methyl-2-pyrollidone, N-vinyl-2-pyrrolidone, γ-butylrolactone, 1,3-dimethyl-2-imidazolizine, sulforane, formamide, N, N-dimethylformamide, N, N-diethylformamide, N-methylformamide, acetoamide, N-methylacetoamine, α-terpeneol, ethylene carbonate, propylene carbonate, bis-α-hydroxyethylsulfone, bis-α-hydroxyethyl urea, N, N-diethylethanolamine, abietinol, diacetone alcohol, urea or the like.

Further, it may be light water, heavy water, and the mixture thereof. Usually, water is referred to as light water with respect to heavy water. Heavy water means water whose hydrogen atoms and/or oxygen atoms are composed of the isotope. Specifically, heavy water includes the followings.

(1) Water including isotope ²H (D) in which one neutron is added to hydrogen atom H (Chemical formula D₂O).

(2) Water including isotope ³H (T) in which two neutrons are added to hydrogen atom H (Chemical formula T₂O).

(3) Water including isotopes ¹⁷O, ¹⁸O of oxygen atoms.

### (Fine Particles)

The particle size of the fine particles used in the present invention may preferably be 0.5 to 8 μm and more preferably be 2 to 7 μm.

The fine particles used in the present invention is not particularly limited.

The material of the fine particles is not particularly limited and may be a resin, an organic material, an inorganic material, the compounds and mixtures thereof.

The resin is not particularly limited and, for example, includes linear or bridged high molecular polymers such as polyethylene, polypropylene, polymethylpentene, polyvinyl chloride, polytetrafluoroethylene, polystyrene, polymethylmetacrylate, polyethylene terephthalate, polybutylene terephthalate, polyamide, polyimide, polysulfone, polyphenylene oxide, polyacetal or the like; and resins having bridged structure such as epoxy resin, phenol resin, melamine resin, benzoguanamine resin, unsaturated polyester resin, divinylbenzene polymer, divinylbenzene-styrene copolymer, divinylbenzene-acrylic ester copolymer, diallylphthalate polymer, triallylisocyanulate polymer or the like.

Further, the organic material includes silica or the like.

The method of producing the fine particles is not particularly limited, and the fine particles may be made by known methods such as polymerization including emulsion polymerization, dispersion polymerization, suspension polymerization, seed polymerization or the like; particle precipitation and granulation from a solution dissolving a polymer material into a solvent; or a method of grinding a polymer material to particles.

Further, a resin may be coated on the fine particles. In this case, the kind of the coating resin is not particularly limited. The coating resin may include one or more functional group(s) selected from the group consisting of alkyl, hydroxyl, epoxy, carboxyl, amino and amide groups.

For example, the resin may be a thermoplastic resin such as polymers or copolymers of monomers composed of a vinyl series compound (CH₂═C(R₁-R₂) whose R₁ and R₂ are hydroxyl or epoxy group, including polyvinyl alcohol, poly-2-hydroxyethyl methacrylate and polyglycidyl methacrylate; a thermosetting resin such as epoxy, phenol and melamine resins; and the mixtures thereof, although the coating resin is not particularly limited as far as the resin has the above described functional groups. It is further preferred that the coating resin is not only physically bonded but also chemically bonded to the particles.

According to a preferred embodiment, in the fine particles, the polymer forming the attached coating is bonded with the particle surface by covalent bonding. The method includes graft polymerization and polymer reaction method. In the graft polymerization method, the following two methods are included: a method of introducing polymerizable vinyl groups onto the particle surface and of polymerizing the monomers from the vinyl groups as the starting points, and a method of introducing a polymerization initiator on the particle surface for polymerizing the monomers by the initiator.

Further, commercially available fine particles may be used. Such commercially available fine particles include “NATOCO SPACER” supplied by Natoco Co. Ltd., “Micro Pearl” supplied by Sekisui chemical Kogyo Co. Ltd., “EPOSTAR”, “SOLIOSTAR” and “SEAHOSTAR” supplied by NIPPON SHOKUBAI KAGAKU KOGYO, “CHEMISNOW” supplied by Soken Kagaku Co. Ltd., “TOSPEARL” supplied by GE Toshiba Silicone Co. Ltd. and “HAYABEADS” supplied by Hayakawa Rubber Co. LTD., although it is not particularly limited to the above lists.

### (Sugars and Sugar Alcohols)

Sugar and/or sugar alcohol may be added to the dispersion.

The sugar alcohol includes, for example, D-threitol, L-threitol, erythritol, D-arabitol, L-arabitol, ribitol, xylitol, arodulcitol, dulcetol, D-talitol, L-talitol, D-iditol, L-iditol, D-mannitol, L-mannitol, D-sorbitol, L-sorbitol, myo-multitol, inositol or the like.

### (Sugar)

Monosaccharides include D-threose, L-threose, D-erythrose, L-erythrose, D-arabinose, L-arabinose, D-ribose, L-ribose, D-xylose, L-xylose, D-lyxose, L-lyxose, D-allose, L-allose, D-altrose, L-altorose, D-glucose, L-glucose, D-mannose, L-mannose, D-gulose, L-gulose, D-idose, L-idose, D-galactose, L-galactose, D-talose, L-talose, D-fluctose, L-fluctose or the like.

Disaccharides include maltose, isomaltose, cellobiose, lactose, sucrose, trehalose, isotrehalose, gentiobiose, melibiose, turanose, sopholose, isosaccharose, or the like.

Polysaccharides of trisaccharides or more include homoglucans such as glucan, fluctan, mannan, xylane, galacturonan, mannuronan, N-acetylglucosamine polymer, and heteroglycans such as diheteroglycan, triheteroglycan or the like.

### (Composition)

The added amount of the adhesive additive may preferably be 1 weight parts or more and 500 weight parts or less with respect to 100 weight parts of the particles. By adding 1 weight parts or more of the additive, the adhesive force can be further improved. By adding 500 weight parts or less of the additive, it becomes easier to fill the adhesive additive under the particles so as to prevent the contamination of alignment films by the adhesive additive. On the viewpoint, the added amount of the adhesive additive may more preferably be 2 weight parts or more, and preferably be 200 weight parts or less, more preferably be 100 weight parts or less and most preferably be 50 weight parts or less.

It is preferred to use 500 to 100000 weight parts of the solvent with respect to 100 weight parts of the particles. When the amount of the solvent is less than 500 weight parts with respect to 100 weight parts of the particles, the drawing performance may be fluctuated. Further, the added amount of the solvent is larger than 100000 weight parts with respect to 100 weight parts of the particles, the ratio of the presence of the particle per a single dot is lowered and many dots including no particle are produced. On the viewpoint, the amount of the solvent may preferably be 1000 weight parts or more or 20000 weight parts or less with respect to 100 weight parts of the particles.

The total amount of the sugar and sugar alcohol may preferably be 1 to 70 weight parts and more preferably be 5 to 60 weight parts, with respect to 100 weight parts of the total amount of the dispersing medium, sugar and sugar alcohol, on the viewpoint of the present invention.

It is preferred that the dispersing medium contains water. In this case, the content of water may preferably be 5 to 85 weight parts with respect to 100 weight parts of the total content of the dispersing medium, sugar and sugar alcohol.

### (Method of Producing a Liquid Crystal Displaying Device)

The method of producing a liquid crystal displaying device is not particularly limited, as far as it includes a step of positioning spacers on a substrate by means of an ink jet printing system.

For example, a first substrate without the positioned spacers and a second substrate with the positioned spacers are opposed to each other through a sealant on the circumference of the substrates and then pressed and heated to form a space therebetween, into which liquid crystal is filled by means of vacuum injection to produce a liquid crystal displaying device.

Alternatively, so called liquid crystal dropping method may be used to produce a liquid crystal displaying device, in which a sealant is applied on the circumference of a first substrate, liquid crystal is then dropped into an area surrounded by the sealant, a second substrate is bonded to the first substrate and the sealant is hardened. In this case, the spacers may be positioned on the substrate to which the liquid crystal is dropped, or on the substrate to be subsequently joined.

### (Drying Condition)

The temperature of drying the liquid drops may preferably be 120° C. or lower. When the liquid drops are given at a temperature exceeding 120° C., there would be a risk of contamination of the alignment films. The temperature may more preferably be 90° C. or lower.

### (Adhesion Condition)

The adhesion temperature may preferably be 120 to 250° C. When it is below 120° C., a sufficiently high adhesive force might not be obtained. When it exceeds 250 r, there would be a risk of adversely affecting the substrate materials such as alignment films. It may more preferably be 150 to 220° C.

### (pH of the Dispersion)

pH of the dispersion may preferably be neutral. When the pH is acidic or alkaline and the solvent includes water or the like, the alignment films tend to be vulnerable to hydrolyzation. The pH may preferably be 4 to 10 and more preferably be 6 to 8.

### EXAMPLES

### (Production of Spacer Particles)

400 g of 3.5% methanol solution of polyvinylpyrrolidone, 42 g of styrene and 63 g of p-trimethoxysilylstyrene are charged into 2 L separable flask and heated to 60° C. under nitrogen gas flow upon gentle stirring. 4 g of azobisisobutyronitrile is added and reacted for 12 hours. After the completion of the reaction, the reaction mixture was cooled to room temperature, 200 g of 5% aqueous solution of potassium hydroxide was added and heated at 60° C. for two hours upon stirring to perform the hydrolyzation and bridging reaction. Further, 20 g of trimethylolpropane thioglycidyl ether was subjected to seed polymerization, dried and then subjected to thermal bridging reaction at 200° C. Spacer particles A having hydroxyl and epoxy groups on the particle surface were thereby obtained.

The spacers A were dispersed in 30 g of methyl ethyl ketone, 3 g of methacryloyl isocyanate was charged, then reacted at room temperature for 30 minutes and washed to obtain spacers B having polymerizable vinyl groups on the surface of the bridged polymer particles A.

To 1 g of the bridged polymer particles B having polymerizable vinyl groups on the surface, 20 g of mixed solution of ethanol, isopropanol and methyl ethyl ketone, 10 g of N-hydroxy ethyl acrylic amide and 0.1 g of azobis 2-methylbutyronitrile were charged in a reactor. The mixture was heated to 75° C. under nitrogen flow and then reacted for 90 minutes. Thereafter, it was washed with methanol to obtain spacers C having graft polymer layer of methoxy N-hydroxyethylacrylic amide on the surface.

### Production of Dispersion 1

### Example 1

The spacers C were dispersed in mixed solvent of glycerin/water/isopropanol in a ratio of 60/35/5 (weight ratio, referred to as mixed solvent 1 below) so that the mixed solvent, spacers and 2,4-dihydroxymethyl 6-methylphenol (abbreviated as 46DMOC below) were mixed in a ratio of 100, 1 and 0.1 (weight ratio). The mixture was filtered through a stainless steel mesh having a mesh size of 20 μm to obtain dispersion 1, which was ultrasonically dispersed.

### Production of Dispersion 2

### Example 2

The mixed solvent 1, the particles and 46DMOC were mixed in a weight ratio of 100:1:0.01 to obtain dispersion 2.

### Production of Dispersion 3

### Example 3

Glycerin, water and acetone were mixed in a weight ratio of 50:20:30 to obtain mixed solvent (referred to as mixed solvent 2). The mixed solvent 1, the particles of the spacer C and 46DMOC were mixed in a weight ratio of 100:1:1 to obtain dispersion 3.

### Production of Dispersion 4

### Example 4

46DMOC was heated at 200° C. for 10 minutes to obtain polymer 1 of 46DMOC having an average molecular weight Mw of 3557. The mixed solvent 2, the particles and 46 DMOC polymer were mixed in a weight ratio of 100, 1 and 0.1 to obtain dispersion 4.

### Production of Dispersion 5

### Example 5

The mixed solvent 1, the particles and 2,6-dihydroxymethyl 4-methyl phenol (abbreviated as 26DMPC below) were mixed in a weight ratio of 100, 1 and 0.1 to obtain dispersion 5.

### Production of Dispersion 6

### Example 6

The mixed solvent 1, the particles and bis(4-hydroxymethyl 5-methylphenyl)methane were mixed in a weight ratio of 100, 1 and 0.1 to obtain dispersion 6.

### Production of Dispersion 7

### Example 7

The mixed solvent 1, the particles and 2,4,6-trimethylolphenol were mixed in a weight ratio of 100, 1 and 0.15 to obtain dispersion 7. The 2,4,6-trimethylolphenol was added as 67% aqueous solution.

### Production of Dispersion 8

### Example 8

The mixed solvent 1, the particles and “ECO ACCORD” (supplied by Kyushu Mokuzai Kougyou Co. Ltd.: methylol phenol) were mixed in a weight ratio of 100, 1 and 0.25 to obtain dispersion 8. “ECO ACCORD” was used as 40% aqueous solution.

### Production of Dispersion 9

### Example 9

The mixed solvent 1, the particles and 8-glysidoxypropyltrimethoxysilane were mixed in a weight ratio of 100, 1 and 0.1 to obtain dispersion 9.

### Production of Dispersion 10

### Example 10

The mixed solvent 1, the particles and 3-glysidoxypropyltriethoxysilane were mixed in a weight ratio of 100, 1 and 0.1 to obtain dispersion 10.

### Production of Dispersion 11

### Example 11

The mixed solvent 1, the particles and 3-glysidoxypropyldimethoxysilane were mixed in a weight ratio of 100, 1 and 0.1 to obtain dispersion 11.

### Production of Dispersion 12

### Example 12

The mixed solvent 1, the particles and γ-isocyanatepropyltriethoxysilane were mixed in a weight ratio of 100, 1 and 0.1 to obtain dispersion 12.

### Production of Dispersion 13

### Example 13

The mixed solvent 1, the particles and bis(trimethoxysilyl)ethane were mixed in a weight ratio of 100, 1 and 0.1 to obtain dispersion 13.

### Production of Dispersion 14

### Example 14

The spacers C was mixed with mixed solvent (referred to as mixed solvent 3 below) of glycerin, heavy water, tetraethyleneglycol and tertially butyl alcohol in a weight ratio of 50, 42, 5 and 3 so that the mixed solvent, the particles and 2,4,6-trimethylolphenol were mixed in a weight ratio of 100, 1 and 0.15, to obtain dispersion 14.

### Production of Dispersion 15

### Example 15

The spacers C was mixed with mixed solvent (referred to as mixed solvent 4 below) of glycerin, heavy water, ethyleneglycol and cyclohexanol in a weight ratio of 50, 40, 9 and 1 so that the mixed solvent, the particles and 2,4,6-trimethylolphenol were mixed in a weight ratio of 100, 1 and 0.15 to obtain dispersion 15.

### Production of Dispersion 16

### Example 16

The spacers C was mixed with mixed solvent (referred to as mixed solvent 5 below) of glycerin, threitol, light water and tertially butyl alcohol in a weight ratio of 15, 40, 42 and 3 so that the mixed solvent, the particles and 2,4,6-trimethylolphenol were mixed in a weight ratio of 100, 1 and 0.15, to obtain dispersion 16.

### Production of Dispersion 17

### Example 17

The mixed solvent 1, the particles and “NIKALAC MX-035” supplied by Nippon carbide industries Co. Inc. were mixed in a ratio of 100, 1 and 0.1 to obtain dispersion 17.

### Production of Dispersion 18

### Example 18

The mixed solvent 1, the particles and “NIKALAC MX-022” supplied by Nippon carbide industries Co. Inc. were mixed in a ratio of 100, 1 and 0.1 to obtain dispersion 18.

### Production of Dispersion 19

### Example 19

The mixed solvent 1, the particles and “NIKALAC MX-012LF” supplied by Nippon carbide industries Co. Inc. were mixed in a ratio of 100, 1 and 0.1 to obtain dispersion 19.

### Production of Dispersion 20

### Example 20

46DMOC was heated at 200° C. for 6 minutes to obtain polymer 4 of 46DMOC having an average molecular weight of 1255. The mixed solvent 2, the particles and the 46DMOC polymer were mixed in a weight ratio of 100, 1 and 0.1 to obtain dispersion 20.

### Production of Dispersion 21

### Example 21

The mixed solvent 3, the particles and the 46DMOC were mixed in a weight ratio of 100, 1 and 2 to obtain dispersion 21.

### Production of Dispersion 22

### Comparative Example 1

The mixed solvent 1 and the particles were mixed in a weight ratio of 100 and 1 to obtain dispersion 22.

### Production of Dispersion 23

### Comparative Example 2

The mixed solvent 2 and the particles were mixed in a weight ratio of 100 and 1 to obtain dispersion 23.

### Production of Dispersion 24

### Comparative Example 3

The mixed solvent 3 and the particles were mixed in a weight ratio of 100 and 1 to obtain dispersion 24.

### Production of Dispersion 25

### Comparative Example 4

The mixed solvent 4 and the particles were mixed in a weight ratio of 100 and 1 to obtain dispersion 25.

### Production of Dispersion 26

### Comparative Example 5

The mixed solvent 5 and the particles were mixed in a weight ratio of 100 and 1 to obtain dispersion 26.

### Production of Dispersion 27

### Comparative Example 6

The mixed solvent 1, the particles and “TANAC” (supplied by Nissan Chemical Industries Ltd.: tris(2-hydroxyethyl)isocyanulate) were mixed in a weight ratio of 100, 1 and 0.1 to obtain dispersion 27.

### Production of Dispersion 28

### Comparative Example 7

46DMOC was heated at 200° C. for 12 minutes to obtain the 46DMOC polymer 2 having an average molecular weight (Mw) of 4657. The mixed solvent 2, the particles and the 46DMOC polymer 2 were mixed in a weight ratio of 100, 1 and 0.1 to obtain dispersion 28.

### Production of Dispersion 29

### Comparative Example 8

46DMOC was heated at 200° C. for 15 minutes to obtain a 46DMOC polymer 3 having an average molecular weight (Mw) of 6001. The mixed solvent 2, the particles and the 46DMOC polymer 3 were mixed in a weight ratio of 100, 1 and 0.1 to obtain dispersion 29.

### Production of Dispersion 30

### Comparative Example 9

The mixed solvent 1, the particles and “Carbo-dilite VO2-L2” (supplied by Nisshinbo Holdings Inc.; Polycarbodiimide series resin) were mixed in a weight ratio of 100, 1 and 0.25 to obtain dispersion 30.

### Production of Dispersion 31

### Comparative Example 10

The mixed solvent 1, the particles and polyvinylpyrrolidinone (K=30) supplied by KANTO CHEMICAL CO., INC. were mixed in a weight ratio of 100, 1 and 0.1 to obtain dispersion 31.

### Production of Dispersion 32

### Comparative Example 11

The mixed solvent 1, the particles and “Epocross WS300” were mixed in a weight ratio of 100, 1 and 0.1 to obtain dispersion 32.

### Production of Dispersion 33

### Comparative Example 12

46DMOC was heated at 200° C. for 11 minutes to obtain 46DMOC polymer 5 having an average molecular weight (Mw) of 3885. The mixed solvent 2, the particles and the 46DMOC polymer 5 were mixed in a ratio of 100, 1 and 0.1 to obtain dispersion 33.

Liquid crystal displaying devices for evaluation were produced according to the following procedure.

First, the thus produced dispersions were used to position spacers on non-pigment sections on a substrate on the side of a color filter, by means of an ink jet printing system mounting a head of piezoelectric system equipped with a nozzle of a diameter of 30 μm on the tip end. The width of the non-pigment sections of the substrate on the side of the color filter was 30 μm, and liquid droplets having a size of 50 μm were attached onto the non-pigment sections.

Thereafter, the substrate was contained in a clean oven whose inner temperature was adjusted at 90° C. and heated for 10 minutes to dry the droplets. Further, the temperature was elevated at 200° C. and the substrate was heated for 30 minutes to adhere the spacers onto the substrate. After the substrate was cooled, sealant was applied on the periphery of the substrate and liquid crystal was dropped onto a region surrounded by the sealant. The substrate was adhered to a driving substrate and the sealant was solidified by heating and UV irradiation to produce a liquid displaying device of 32 inches.

Further, the following simple substrate was produced and evaluated for the adhesive force.

### (Method of Producing a Cell for Two Fluid Blow Evaluation of Adhesion Force)

The thus produced dispersion was printed on a soda glass with ITO (supplied by Opto Science, Inc) applied with PI (Nissan Chemical Industries Ltd., SE-7492) and rubbed, by means of an ink jet printing system according to piezoelectric system and equipped with a nozzle of a diameter of 30 μm on the tip end. The glass was then heated in a clean oven at 00° C. for 10 minutes to dry the droplets and further heated at 200° C. for 30 minutes for the adhesion.

### (Method of Two Fluid Blow Evaluation of Adhesion Force)

The substrate after the adhesion procedure of the spacers was blown by two kinds of fluids of air and water with a spray gun, and the number of dots whose spacers were moved after the blow were counted in 100 dots to calculate adhesion ratio for evaluating the adhesion force. The blowing of the two kinds of fluids was carried out at blow pressures of 0.2 MPa and 0.3 MPa, a distance between the nozzle tip end of the spray gun and substrate of 60 mm and a time period of 20 sec.

◯: The spacers were not moved after the blow.

Δ: A part of the spacers was moved after the blow.

X: All the spacers were moved after the blow.

### (Evaluation of Adhesion Force of Liquid Crystal Displaying Device)

### (Shaking Test Condition)

The adhesion force of the spacers was evaluated by means of a single-axis shaking test system.

The respective dispersions were used to produce the 32-inch panels, which were fixed in a shaking test system and shaken according to the following condition for 30 minutes in x, y and z directions, respectively.

Acceleration: 2 G

### (Evaluation of Adhesion Force on Shaking)

∘: The movement of the spacers was not observed.

x: The movement of the spacers was observed.

### (Evaluation on Displayed Image of Liquid Crystal Displaying Device)

### (Evaluation of Quality of Displayed Image)

∘: It is not observed spot-like light leakage, in pigment sections, which is considered to be caused by contamination of alignment films.

x: It is observed spot-like light leakage, in pigment sections, which is considered to be caused by contamination of alignment films.

Further, for evaluating the contamination of alignment films, the following simple panel was produced and evaluated.

### (Method of Evaluating Contamination of Alignment Films in a Simple Cell)

The spacers were adhered to a substrate, which was then used to produce a cell. Liquid crystal (supplied by Merck Ltd. Japan, MLC-6222) was injected into the cell to produce a panel. An alternating current voltage (AC) of 3 Vrms was applied on the liquid crystal panel to confirm the state of the alignment film.

### (Standards for Evaluating Contamination of Alignment Films in Simple Cell)

∘: In the case that the adhesive component selectively aggregates around the spacers and the area of the contaminated regions of the alignment films is considerably smaller than that of the droplets before drying.

x: In the case that it is observed the adhesive component with a substantially same size as the droplets before the drying to contaminate the alignment films.

### (Measurement of Molecular Weight)

It was measured by means of high performance GPC system (HLC-8220GPC) manufactured by TOSOH CORPORATION. Tetrahydrofuran was used as the diluting solvent.

(Solubility after the Heating)

It was measured the solubilities with respect to generally used solvents (hexane, cyclohexane, toluene, ethyl acetate, tetrahydrofuran, benzene, methyethylketone, chloroform, acetone, acetonitryl, dimethylformamide, ethanol, dimethylsulfoxide, methanol, and water). In the examples using 2,4,6-trimethylolphenol, ECO ACCORD (Examples 7, 8, 14, 15 and 16), it was dissolved in water before the heating and not soluble in all the solvents after the heating.

Remarks 1: The molecular weights of “EPOCROSS WS300” and polyvinylpyrrolidinone (K=30) were referred to in Catalogues supplied by the suppliers.

TABLE 1

| Example No. | | Ex. 1 | Ex. 2 | Ex. 3 | Ex. 4 | Ex. 5 |
|---|---|---|---|---|---|---|
| Dispersion No. | | Dispersion 1 | Dispersion 2 | Dispersion 3 | Dispersion 4 | DisperSion 5 |
| Adhesive Component | | 46DMOC | 46DMOC | 46DMOC | 46DMOC | 26DMPC |
| | | | | | Polymer 1 | |
| Addition weight of adhesive | | 10 wt % | 1 wt % | 100 wt % | 10 wt % | 10 wt % |
| With respect to Particles | | | | | | |
| Dispersant | | Mixed | Mixed | Mixed | Mixed | Mixed |
| | | Solvent 1 | Solvent 1 | Solvent 2 | Solvent 2 | Solvent 1 |
| 32″ | Shaking | ◯ | ◯ | ◯ | ◯ | ◯ |
| Panel | Adhesion | | | | | |
| | Evaluation | | | | | |
| | Display Image | ◯ | ◯ | ◯ | ◯ | ◯ |
| | Quality | | | | | |
| | Evaluation | | | | | |
| Simple | Two Fluid Blow | ◯ | Δ | ◯ | ◯ | ◯ |
| sub- | Evaluation | 100% | 80% | 100% | 100% | 100% |
| stRate | (0.2 MPa) | | | | | |
| | Two Fluid Blow | ◯ | Δ | ◯ | Δ | ◯ |
| | Evaluation | 100% | 51% | 100% | 81% | 100% |
| | (0.3 MPa) | | | | | |
| Simple | Contamination | ◯ | ◯ | ◯ | ◯ | ◯ |
| Cell | of alignment | | | | | |
| | film Evaluation | | | | | |

| | | | | | |
|---|---|---|---|---|---|
| Molecular weight | 269 | 269 | 269 | 3557 | 264 |
| before heating (Mw) | | | | | |
| Molecular weight after heating | 22472 | 22472 | 22472 | 41432 | 7310 |
| at 200° C. for 30 minutes (Mw) | | | | | |
| Solubility After Heating* | Dissolved | Dissolved | Dissolved | dissolved | Dissolved |

TABLE 2

| Example No. | | Ex. 6 | Ex. 7 | Ex. 8 | Ex. 9 | Ex. 10 |
|---|---|---|---|---|---|---|
| Dispersion No. | | Dispersion 6 | Dispersion 7 | Dispersion 8 | Dispersion 9 | DisperSion 10 |
| Adhesive Component | | Bis(4-hydroxy- | 2,4,6-tri- | ECO | 3-glysidoxy- | 3-glysidoxy- |
| | | methyl-5-methyl- | methyl- | ACCORD | propyltri- | propyltri- |
| | | phenyl)methane | phenol | | methoxysilane | Ethoxysilane |
| Addition weight of adhesive | | 10 wt % | 10 wt % | 10 wt % | 10 wt % | 10 wt % |
| With respect to Particles | | | | | | |
| Dispersant | | Mixed | Mixed | Mixed | Mixed | Mixed |
| | | Solvent 2 | Solvent 1 | Solvent 1 | Solvent 2 | Solvent 1 |
| 32″ | Shaking | ◯ | ◯ | ◯ | ◯ | ◯ |
| Panel | Adhesion | | | | | |
| | Evaluation | | | | | |
| | Display | ◯ | ◯ | ◯ | ◯ | ◯ |
| | Image Quality | | | | | |
| | Evaluation | | | | | |
| Simple | Two Fluid Blow | ◯ | ◯ | ◯ | ◯ | ◯ |
| sub- | Evaluation | 100% | 100% | 100% | 100% | 100% |
| strate | (0.2 MPa) | | | | | |
| | Two Fluid Blow | ◯ | ◯ | ◯ | ◯ | ◯ |
| | Evaluation | 100% | 100% | 100% | 100% | 100% |
| | (0.3 MPa) | | | | | |
| Simple | Contamination | ◯ | ◯ | ◯ | ◯ | ◯ |
| Cell | of alignment | | | | | |
| | film Evaluation | | | | | |

| | | | | | |
|---|---|---|---|---|---|
| Molecular weight | 378 | 311 | 286 | 246 | 319 |
| Before heating (Mw) | | | | | |
| Molecular weight after heating | 6624 | Un- | Un- | 10266 | 5078 |
| at 200° C. for 30 minutes (Mw) | | measurable | measurable | | |
| Solubility After Heating* | Soluble | Insoluble | Insoluble | Soluble | Soluble |

TABLE 3

| Example No. | | Ex. 11 | Ex. 12 | Ex. 13 | Ex. 14 | Ex. 15 |
|---|---|---|---|---|---|---|
| Dispersion No. | | Dispersion 11 | Dispersion 12 | Dispersion 13 | Dispersion 14 | DisperSion 15 |
| Adhesive Component | | 3-glysidoxy- | γ-isocyanate | Bis(tri- | 2,4,6- | 2,4,6- |
| | | propylmethyl- | propyltri- | methoxy- | trimethylol- | trimethylol- |
| | | dimethoxysilane | ethoxysilane | silyl)ethane | phenol | phenol |
| Addition weight of adhesive | | 10 wt % | 100 wt % | 100 wt % | 10 wt % | 10 wt % |
| with respect to Particles | | | | | | |
| Dispersant | | Mixed | Mixed | Mixed | Mixed | Mixed |
| | | solvent 1 | solvent 1 | solvent 1 | solvent 3 | solvent 4 |
| 32″ | Shaking | ◯ | ◯ | ◯ | ◯ | ◯ |
| Panel | Adhesion | | | | | |
| | Evaluation | | | | | |
| | Display | ◯ | ◯ | ◯ | ◯ | ◯ |
| | Image Quality | | | | | |
| | Evaluation | | | | | |
| Simple | Two Fluid Blow | ◯ | ◯ | ◯ | ◯ | ◯ |
| sub- | Evaluation | 100% | 100% | 100% | 100% | 100% |
| stRate | (0.2 MPa) | | | | | |
| | Two Fluid Blow | ◯ | ◯ | ◯ | ◯ | ◯ |
| | Evaluation | 100% | 100% | 100% | 100% | 100% |
| | (0.3 MPa) | | | | | |
| Simple | Contamination | ◯ | ◯ | ◯ | ◯ | ◯ |
| Cell | of alignment | | | | | |
| | film Evaluation | | | | | |

| | | | | | |
|---|---|---|---|---|---|
| Molecular weight | 243 | 305 | 288 | 311 | 311 |
| before heating (Mw) | | | | | |
| Molecular weight after heating | 4629 | 6030 | 7213 | Un- | Un- |
| at 200° C. for 30 minutes (Mw) | | | | measurable | measurable |
| Solubility After Heating* | Soluble | Soluble | Soluble | Insoluble | Insoluble |

TABLE 4

| Example No. | | Ex. 16 | Ex. 17 | Ex. 18 | Ex. 19 | Ex. 20 | Ex. 21 |
|---|---|---|---|---|---|---|---|
| Dispersion No. | | Dispersion 16 | Dispersion 17 | Dispersion 18 | Dispersion 19 | Dispersion 20 | Dispersion 21 |
| Adhesive Component | | 2,4,6- | NIKALAC | NIKALAC | NIKALAK | 46DMOC | 46DMOC |
| | | trimethylol- | MX-035 | MX-022 | MX-012LF | Polymer4 | |
| | | phenol | | | | | |
| Addition weight of adhesive | | 10 wt % | 10 wt % | 10 wt % | 10 wt % | 10 wt % | 200 wt % |
| with respect to Particles | | | | | | | |
| Dispersant | | Mixed | Mixed | Mixed | Mixed | Mixed | Mixed |
| | | solvent 1 | solvent 1 | solvent 1 | solvent 1 | solvent 4 | solvent 3 |
| 32″ | Shaking | ◯ | ◯ | ◯ | ◯ | ◯ | ◯ |
| Panel | Adhesion | | | | | | |
| | Evaluation | | | | | | |
| | Display | ◯ | ◯ | ◯ | ◯ | ◯ | ◯ |
| | Image Quality | | | | | | |
| | Evaluation | | | | | | |
| Simple | Two Fluid Blow | ◯ | ◯ | ◯ | ◯ | ◯ | ◯ |
| sub- | Evaluation | 100% | 100% | 100% | 100% | 100% | 100% |
| strate | (0.2 MPa) | | | | | | |
| | Two Fluid Blow | ◯ | ◯ | ◯ | ◯ | Δ | ◯ |
| | Evaluation | 100% | 100% | 100% | 100% | 91% | 100% |
| | (0.3 MPa) | | | | | | |
| Simple | Contamination | ◯ | ◯ | ◯ | ◯ | ◯ | ◯ |
| Cell | of alignment | | | | | | |
| | film Evaluation | | | | | | |

| | | | | | | |
|---|---|---|---|---|---|---|
| Molecular weight | 243 | 661 | 950 | 765 | 1255 | 243 |
| Before heating (Mw) | | | | | | |
| Molecular weight after heating | Un- | 4554 | 3714 | 3967 | 29452 | Un- |
| at 200° C. for 30 minutes (Mw) | measurable | | | | | measuRable |
| Solubility after Heating* | Insoluble | Soluble | Soluble | Soluble | Soluble | Insoluble |

TABLE 5

| Comparative Example No. | | Com. Ex. 1 | Com. Ex. 2 | Com. Ex. 3 | Com. Ex. 4 | Com. Ex. 5 |
|---|---|---|---|---|---|---|
| Dispersion No. | | Dispersion 22 | Dispersion 23 | Dispersion 24 | Dispersion 25 | Dispersion 26 |
| Adhesive Component | | None | None | None | None | None |
| Addition weight of adhesive | | 0 wt % | 0 wt % | 0 wt % | 0 wt % | 0 wt % |
| with respect to Particles | | | | | | |
| Dispersant | | Mixed | Mixed | Mixed | Mixed | Mixed |
| | | solvent 1 | solvent 2 | solvent 3 | solvent 4 | solvent 5 |
| 32″ | Shaking | X | X | X | X | X |
| Panel | Adhesion | | | | | |
| | Evaluation | | | | | |
| | Display | ◯ | ◯ | ◯ | ◯ | ◯ |
| | Image Quality | | | | | |
| | Evaluation | | | | | |
| Simple | Two Fluid Blow | X | X | X | X | X |
| sub- | Evaluation | 0% | 0% | 0% | 0% | 0% |
| strate | (0.2 MPa) | | | | | |
| | Two Fluid Blow | X | X | X | X | X |
| | Evaluation | 0% | 0% | 0% | 0% | 0% |
| | (0.3 MPa) | | | | | |
| Simple | Contamination | ◯ | ◯ | ◯ | ◯ | ◯ |
| Cell | of alignment | | | | | |
| | film Evaluation | | | | | |

| | | | | | |
|---|---|---|---|---|---|
| Molecular weight | — | — | — | — | — |
| Before heating (Mw) | | | | | |
| Molecular weight after heating | — | — | — | — | — |
| at 200° C. for 30 minutes (Mw) | | | | | |
| Solubility after Heating* | — | — | — | — | — |

TABLE 6

| Comparative Example No. | | Com. Ex. 6 | Com. Ex. 7 | Com. Ex. 8 | Com. Ex. 9 | Com. Ex. 10 |
|---|---|---|---|---|---|---|
| Dispersion No. | | Dispersion 27 | Dispersion 28 | Dispersion 29 | Dispersion 30 | Dispersion 31 |
| Adhesive Component | | TANAC | 46DMOC | 46DMOC | CARBODI- | Polyvinyl |
| | | | polymer 2 | Polymer 3 | LITE | Pyrrolidinone |
| | | | | | V02-L2 | (K = 30) |
| Addition weight of adhesive | | 10 wt % | 10 wt % | 10 wt % | 10 wt % | 10 wt % |
| with respect to Particles | | | | | | |
| Dispersant | | Mixed | Mixed | Mixed | Mixed | Mixed |
| | | Solvent 1 | Solvent 2 | Solvent 2 | Solvent 1 | Solvent 1 |
| 32″ | Shaking | X | ◯ | ◯ | ◯ | ◯ |
| Panel | Adhesion | | | | | |
| | Evaluation | | | | | |
| | Display | ◯ | X | X | X | X |
| | Image Quality | | | | | |
| | Evaluation | | | | | |
| Simple | Two Fluid Blow | X | ◯ | ◯ | ◯ | ◯ |
| sub- | Evaluation | 0% | 100% | 100% | 100% | 100% |
| stRate | (0.2 MPa) | | | | | |
| | Two Fluid Blow | X | Δ | Δ | Δ | ◯ |
| | Evaluation | 0% | 75% | 81% | 66% | 57% |
| | (0.3 MPa) | | | | | |
| Simple | Contamination | ◯ | X | X | X | X |
| Cell | of alignment | | | | | |
| | film Evaluation | | | | | |

| | | | | | |
|---|---|---|---|---|---|
| Molecular weight | 347 | 4657 | 6001 | 7077 | 40000** |
| Before heating (Mw) | | | | | |
| Molecular weight after heating | 348 | 23187 | 24228 | 7152 | — |
| at 200° C. for 30 minutes (Mw) | | | | | |
| Solubility after Heating* | Soluble | Soluble | Soluble | Soluble | Insoluble |

TABLE 7

| | | Comparative | |
|---|---|---|---|
| | | Example No. | |
| | | Com. Ex. 11 | Com. Ex. 12 |
| Dispersion No. | | Dispersion 32 | Dispersion 33 |
| Adhesive | | EPOCROSS | 46DMOC |
| Component | | WS300 | Polymer 5 |
| Addition weight of adhesive | | 10 wt % | 10 wt % |
| with respect to Particles | | | |
| Dispersant | | Mixed solvent 1 | Mixed solvent 2 |
| 32″ | Shaking | ◯ | ◯ |
| Panel | Adhesion | | |
| | Evaluation | | |
| | Display Image | X | X |
| | Quality | | |
| | Evaluation | | |
| Simple | Two Fluid Blow | ◯ | ◯ |
| substrate | Evaluation (0.2 MPa) | 100% | 100% |
| | Two Fluid Blow | Δ | Δ |
| | Evaluation (0.3 MPa) | 77% | 80% |
| Simple | Contamination | X | X |
| Cell | of alignment film | | |
| | Evaluation | | |

| | | |
|---|---|---|
| Molecular weight before heating | 120000** | 3885 |
| (Mw) | | |
| Molecular weight after heating | — | 27824 |
| at 200° C. for 30 minutes (Mw) | | |
| Solubility after Heating* | Insoluble | Soluble |

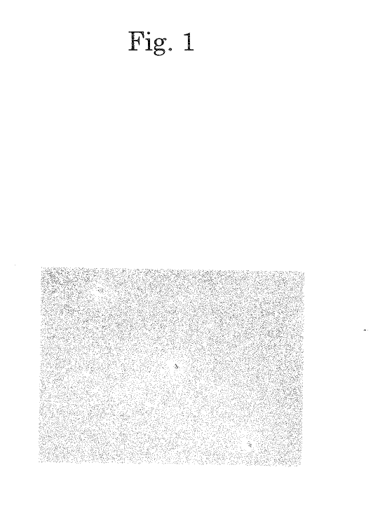

According to the examples, it is used the adhesive additive having an average molecular weight (Mw) of 3600 or lower and properties of polymerizing or forming insoluble material after printing the liquid droplets, drying and adhering upon heating. It is thereby confirmed that a strong adhesion force can be obtained without contamination of alignment films in the regions where the liquid droplets exist, as shown in a photograph of FIG. 1. The adhesion force can be further improved by making the average molecular weight (Mw) lower than 1000.

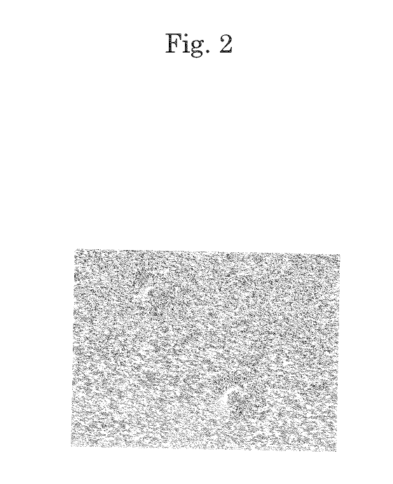

On the other hand, when it is used the adhesive component having a molecular weight larger than 3600 as in the comparative examples 7 to 12, it is confirmed contamination of alignment films in the regions where the liquid droplets exist, as shown in a photograph of FIG. 2, although a strong adhesion force can be obtained.

Further, when it is used the adhesive component having a low molecular weight and which does not polymerize upon heating as in the comparative example 6, a strong adhesion force cannot be obtained.

The present invention has been explained referring to the preferred embodiments, however, the present invention is not limited to the illustrated embodiments which are given by way of examples only, and may be carried out in various modes without departing from the scope of the invention.

1. A dispersion for positioning and adhering fine particles at predetermined positions on a substrate upon heating by ink jet printing, said dispersion comprising spacers, a solvent and an adhesive additive, wherein said adhesive additive has an average molecular weight (Mw) of 3600 or lower and a property of polymerizing upon heating.

2. The dispersion of claim 1, wherein said adhesive additive has a weight average molecular weight (Mw) of 3600 or lower (excluding 1000 or more).

3. The dispersion of claim 1, wherein said adhesive additive comprises a phenol methylol compound having a plurality of methylol groups.

4. The dispersion of claim 1, wherein said adhesive additive comprises a silane compound having a plurality of hydrolysable alkoxy groups in a molecule.

5. The dispersion of claim 1, wherein said adhesive additive forms an insoluble substance upon said heating with respect to tetrahydrofuran.

6. A method of producing a liquid crystal display device, the method comprising the steps of:
positioning said dispersion of claim 1 on non-displaying sections of at least one of a first substrate and a second substrate by means of a ink jet printing system;
drying said dispersion; and
opposing and then fixing said first and second substrates through said spacers and a liquid crystal.
